(19) United States
(12) Patent Application Publication
(10) Pub. No.: US 2023/0215974 A1
(43) Pub. Date: Jul. 6, 2023

(54) METHODS FOR ENGINEERING VOLUMES IN LEDS FOR HIGHER OPERATING EFFICIENCIES AND DEVICES THEREOF

(71) Applicant: Matthew T. HARTENSVELD, Wyckoff, NJ (US)

(72) Inventor: Matthew T. HARTENSVELD, Wyckoff, NJ (US)

(21) Appl. No.: 17/565,960

(22) Filed: Dec. 30, 2021

(51) Int. Cl. H01L 33/20

(52) U.S. Cl. CPC H01L 33/20; H01L 33/06

(57) ABSTRACT

A method or system for engineering at least one volume in a light emitting diode (LED) for higher operating efficiency includes forming a first semiconductor region of a light emitting diode doped with a first dopant concentration. A second semiconductor region of the light emitting diode doped with a second dopant concentration coupled to the first semiconductor region is formed. The forming the first semiconductor region or the forming the second semiconductor region further comprises forming a volume of the first semiconductor region or another volume of the second semiconductor region based on a calculation so that an electron concentration in the first semiconductor region or the second semiconductor region substantially matches within a first set percentage a hole concentration in the other one of the first semiconductor region or the second semiconductor region.

This application claims the benefit of U.S. Provisional Patent Application Ser. No. 63/133,769, filed Jan. 4, 2021, which is hereby incorporated by reference in its entirety.

### FIELD

This technology relates to methods for engineering volumes in LEDs for higher operating efficiencies that minimize or eliminate efficiency droop and devices thereof.

### BACKGROUND

Light Emitting Diodes (LEDs) provide efficient lighting for a wide range of applications. Unfortunately, high efficiency LEDs are known to degrade as the current increases, a problem known as the efficiency droop. For devices that desire high brightness, this problem necessitates either the inclusion of more LEDs to compensate, or reduced efficiency.

There are two identified possible causes of this problem, which are under debate, where one is electron auger recombination, and the other is electron leakage. Auger recombination is enhanced when many electrons are in proximity and excite each other to a higher energy state instead of radiatively recombining. Electron leakage is when electrons go past the quantum wells into the p-type GaN layer and non-radiatively recombine with holes. Regardless of the evidence for one or the other as the cause, both point to an excess electron concentration relative to the number of holes where due to the high ionization energy of acceptors, there are significantly fewer holes to the number of electrons. This leads to the poor efficiency at a high LED drive current.

There have been and continue to be many attempts to solve this issue through engineering the various layers which make up an LED. Commonly an electron blocking layer (EBL) is utilized between a p-type layer and multiple quantum wells (MQWs) or between an n-type layer and the MQW. The EBL blocks many electrons and reduces the efficiency droop, though the layer also blocks some holes from being injected into the multiple quantum wells. The obvious solution may seem to be decreasing the n-type doping to reduce the number of electrons, though that negatively impacts resistance in the device. Editing the vertical dopant concentration is difficult, and laterally selective doping can add cost and is impractical in most cases.

By way of further example, a prior art LED 10(1) susceptible to this efficiency droop is illustrated in FIGS. 1A-2A. In these examples, the LED 10(1) is configured in a vertical or stacked arrangement having a p-type layer 12(1) on an MQW region 14(1) on an n-type layer 16(1). This vertical or stacked arrangement is utilized due to the fundamentals of crystal growth, although other examples may exist, such as a different ordering or the inclusion of additional layers. Conventionally, in the MQW region 14(1) of the LED 10(1) the oppositely charged free electrons and free holes recombine, producing light. The supply of free electrons or free holes are provided by donors or acceptors which are dopant atoms introduced into the crystal structure. These donor or acceptor atoms, when integrated in the lattice, possess either an extra electron or a lack of an electron i.e., a ‘hole’, respectively. The region of donor incorporation is conventionally denoted as the n-type layer 16(1) in the LED 10(1), while the region of acceptor incorporation is conventionally denoted as the p-type layer 12(1) in the LED 10(1). An anode contact 19(1) is coupled to the p-type layer 12(1) and a cathode contact 18(1) is coupled to the n-type layer 16(1) which is on a bottom layer 17(1) as shown in FIG. 2A.

An issue that can arise, however, is the potential for high ionization energy between the donor atom and the extra electron, or the acceptor atom and the extra hole. A high ionization energy means that the donor and/or acceptor atoms produce few free electrons or holes, respectively, at room temperature. A lack of free electrons or free holes results in high resistivity for the cathode contact 18(1), high resistivity of the anode contact 19(1), and correspondingly little light output, as both free electrons and free holes are needed to recombine and produce light. The ionization energy is generally a fixed value that is determined by the choice of donor or acceptor atoms and the choice of material these atoms are put into.

A common example of materials used in the prior art LED 10(1) is that of the III-N materials system, which can be made of Al, Ga, and/or In bonded to N. For the supply of electrons to make the n-type layer 16(1) in the LED 10(1), donor atoms of Si are commonly utilized. Where Si has a relatively low ionization energy, such that for every Si donor atom incorporated into the crystal, approximately one free electron is produced at room temperature, i.e. is ionized. In contrast, to supply holes to create the p-type layer 12(1) in the LED 10(1), acceptor atoms of Mg are commonly utilized. Mg, however, has a high ionization energy leading to very few free holes, where there can be far less than 1 free hole for over 100 Mg acceptor atoms incorporated into the crystal, at room temperature. The III-N materials system is often limited to Mg due to a lack of other available choices. The hole ionization energy is also known to greatly increase for Mg acceptor atoms when producing shorter wavelength LEDs, making the issue more detrimental.

The differences in ionization energies between donors and acceptors leads to a large disparity in the free electron and free hole concentrations. The high number of free electrons relative to the number of free holes leads to the common issue known as the efficiency droop. Where at high current, the large number of electrons overwhelm the few holes, leading to non-radiative recombination (heat generation) and a reduction in the total device efficiency. Because the prior art LED 10(1) is conventionally made layer by layer vertically, due to selective area doping constraints, simply lowering the donor concentration in the n-type layer 16(1) in the LED 10(1) might seem like a simple solution. However, lowering the donor concentration in the n-type layer 16(1) leads to a sacrifice in the efficiency of the cathode contact 18(1), and adds resistance to the total device.

### SUMMARY

A method for engineering at least one volume in a light emitting diode (LED) for higher operating efficiency includes forming a first semiconductor region of a light emitting diode doped with a first dopant concentration. A second semiconductor region of the light emitting diode doped with a second dopant concentration coupled to the first semiconductor region is formed. Forming the first semiconductor region or forming the second semiconductor region further comprises forming a volume of the first semiconductor region or another volume of the second semiconductor region based on a calculation so that an electron concentration in the first semiconductor region or the second semiconductor region substantially matches within a first set percentage a hole concentration in the other one of the first semiconductor region or the second semiconductor region.

This technology provides a number of advantages including providing methods for engineering volumes in LEDs for higher operating efficiencies that minimize or eliminate efficiency droop in devices thereof. With examples of this technology, an effective volume of doped layers of an LED are engineered or otherwise formed based on calculations so that electron concentration better matches hole concentration. For example, a more electron rich layer with a smaller volume balances a larger volume with a poor hole concentration. Better matching between electrons and holes with these engineered volumes leads to a reduction in the efficiency droop and promotes other advantages, such as enhanced light extraction efficiency by way of example.

### BRIEF DESCRITION OF THE DRAWINGS

FIG. 1A is a cross-sectional view of an example of a prior art LED susceptible to efficiency droop.

FIG. 1B is a cross-sectional view of an example of an LED in an inverted pyramid shape with an engineered volume for higher operating efficiencies that minimize or eliminate to efficiency droop.

FIG. 1C is a cross-sectional view of an example of another LED in a pyramid shape with an engineered volume for higher operating efficiencies that minimize or eliminate to efficiency droop.

FIG. 2A is a cross-sectional view of the example of the prior art LED shown in FIG. 1A on a bottom layer and with anode and cathode contacts.

FIG. 2B is a cross-sectional view of the example of the LED shown in FIG. 1B on a bottom layer and with anode and cathode contacts.

FIG. 2C is a cross-sectional view of the example of the LED shown in FIG. 1C on a bottom layer and with anode and cathode contacts.

FIG. 3A is a cross-sectional view of another example of an LED in another inverted pyramid shape with an engineered volume for higher operating efficiencies that minimize or eliminate to efficiency droop.

FIG. 3B is a cross-sectional view of another example of an LED in another pyramid shape with an engineered volume for higher operating efficiencies that minimize or eliminate to efficiency droop.

FIG. 3C is a cross-sectional view another example of an LED in a T-shape with an engineered volume for higher operating efficiencies that minimize or eliminate to efficiency droop.

FIG. 4A is a cross-sectional view of the example of the LED shown in FIG. 3A on a bottom layer and with anode and cathode contacts.

FIG. 4B is a cross-sectional view of the example of the LED shown in FIG. 3B on a bottom layer and with anode and cathode contacts.

FIG. 4C is a cross-sectional view of the example of the LED shown in FIG. 3C on a bottom layer and with anode and cathode contacts.

FIG. 5 is a graph of an example of illustrating a reduction in efficiency droop in an LED with an engineered volume.

### DETAILED DESCRIPTION

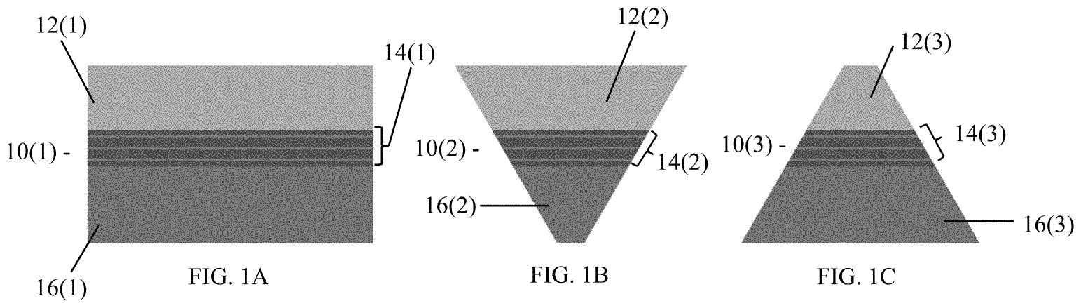

Examples of LEDs 10(2)-10(6) with various engineered volumes for higher operating efficiencies that minimize or eliminate efficiency droop are illustrated in FIGS. 1B, 1C, 2B, 2C, 3A-3C, 4A-4C. In this particular example, each of the LEDs 10(2)-10(6) includes a corresponding one of each of a p-type layers 12(2)-12(6), an MQW regions 14(2)-14(6), and an n-type layers 16(2)-16(6), although the environment could include other types and numbers of systems, devices, components, and/or other elements as is generally known in the art and will not be illustrated or described herein. This technology provides a number of advantages including providing methods for engineering volumes in LEDs for higher operating efficiencies that minimize or eliminate efficiency droop and devices thereof.

In each of these illustrative examples, a volume of a corresponding one of the n-type layers 16(2)-16(6) and/or one of the p-type layers 12(2)-12(6) of the LEDs 10(2)-10(6) is engineered to have a calculated volume to better create a more equal charge distribution without adjusting a dopant concentration of either of the n-type layers 16(2)-16(6) and/or one of the p-type layers 12(2)-12(6) of the LEDs 10(2)-10(6) which results in higher operating efficiencies that minimize or eliminate to efficiency droop. The number of electrons corresponding to one of the n-type layers 16(2)-16(6) and/or holes corresponding to one of the p-type layers 12(2)-12(6), can be calculated by multiplying the ionized donor or acceptor concentration by the volume of the n-type or p-type layer, respectively, such that the chargers can be made equal or otherwise substantially balanced, e.g. within a set percentage of each other, such as within 50% of each other.

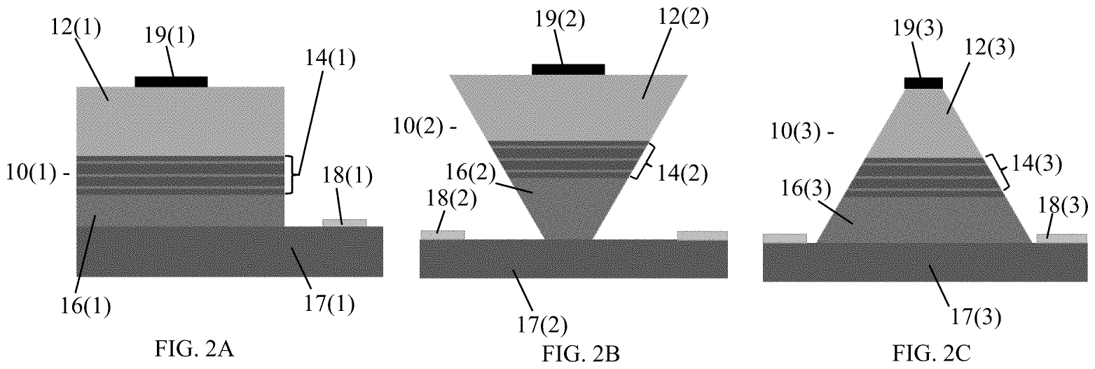

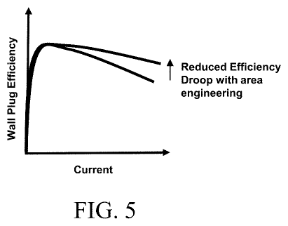

Referring to FIGS. 1B and 2B, a cross-sectional view of an example of an LED 10(2) with an engineered volume in an inverted pyramid shape for higher operating efficiencies that minimize or eliminate efficiency droop is illustrated. The LED 10(2) comprises the p-type layer 12(2), on the MQW region 14(2) which is on the n-type layer 16(2), which is on a bottom layer or substrate 17(2) coupled to a cathode contact 18(2) and an anode contact 19(2) coupled to the p-type layer 12(2), although the LED could have other types of layers and/or other elements in other configurations. Based on the set doping concentrations in the p-type layer 12(2) and the n-type layer 16(2), the LED 10(2) is configured in this example to have an inverted pyramid design to equalize or better balance the number of free holes in the volume of the p-type layer 12(2) to a number of free electrons in volume of the n-type layer 16(2), in the case of a higher acceptor ionization energy. Accordingly, in this example a calculated total volume of the p-type layer 12(2) is larger relative to another calculated total volume of the n-type layer 16(2) based on the identified concentration of charges to produce a more equal free carrier distribution, leading to less efficiency droop as illustrated in FIG. 5.

In this example, the bottom layer 17(1) acts as both a mechanical support and a conductive path for the n-type layer 16(2). The bottom layer 17(1) can share the same dopant concentration or different dopant concentration than the adjacent layer, or different dopant type, for the purpose of facilitating current injection to the n-type layer 16(2). The bottom layer 17(1) in an example could be a semiconductor substrate, a semiconductor layer, or a metallic layer and may comprise other numbers and/or types of layers and/or elements. The bottom layer 17(1) can also be optionally factored into the volume consideration of balancing the number of free electrons and free holes through volume engineering. The bottom layers 17(2)-17(6) have the same structure and operation as illustrated and described with reference to bottom layer 17(1), although one or more could have other configurations in other examples.

Additionally by way of example, such a structure as shown in FIG. 1B can be formed by taking the vertically grown layers in FIG. 1A and performing a selective etch utilizing standard semiconductor techniques, such as with a plasma dry-etch or with a wet hydroxyl-based chemical etch to adjust the respective volumes as needed. Alternatively, the structure shown in FIG. 1B could be formed through a bottom-up growth process. In which the semiconductor structure is selectively grown from a bottom layer or other substrate to engineer volumes of the p-type layer 12(2) and the n-type layer 16(2) to have a calculated equal distribution of charge carriers, e.g. electrons and holes, within a set percentage, such as 50% by way of example. Further, in this example, the conductive contacts 18(2) and 19(2) can be deposited using standard semiconductor techniques such as, but not limited to, thermal evaporator, sputtering, chemical vapor deposition, e-beam evaporator, and atomic layer deposition.

Referring to FIGS. 1C and 2C, a cross-sectional view of an example of an LED 10(3) with an engineered volume in a pyramid shape for higher operating efficiencies that minimize or eliminate efficiency droop is illustrated. The LED 10(3) comprises the p-type layer 12(3), on the MQW region 14(3) which is on the n-type layer 16(3), which is on a bottom layer or substrate 17(3) coupled to a cathode contact 18(3) and an anode contact 19(3) coupled to the p-type layer 12(3), although the LED could have other types of layers and/or other elements in other configurations. In this example, there can exist an opposite situation from that shown in FIGS. 1B and 2B, where in this example in FIGS. 1C and 2C the donor atoms have a higher ionization energy than the acceptor atoms. To address the higher donor atom ionization energy, a pyramidal shape can be formed, in which a volume of the p-type layer 12(3) volume is calculated to be smaller relative to the n-type layer 16(3) so that there is again calculated equal distribution of charge carriers, e.g. electrons and holes, within a set percentage, such as 50% by way of example eliminating or leading to less efficiency droop as illustrated in FIG. 5. By way of example, the LED 10(3) can be formed using similar exemplary techniques to those described above for LED 10(2), although other approaches may be used.

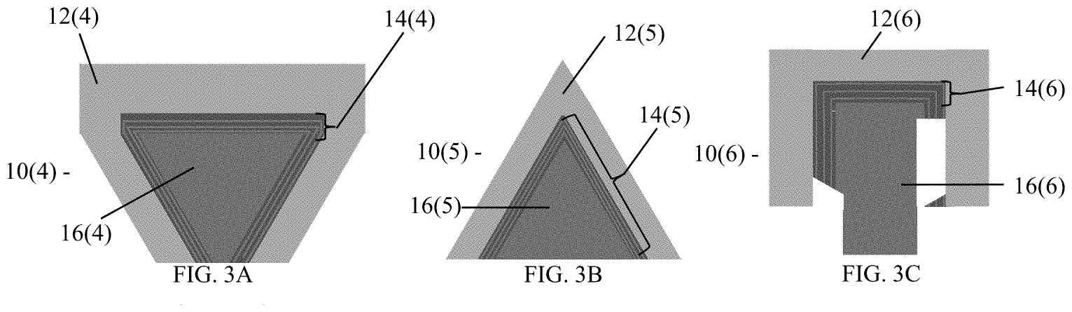

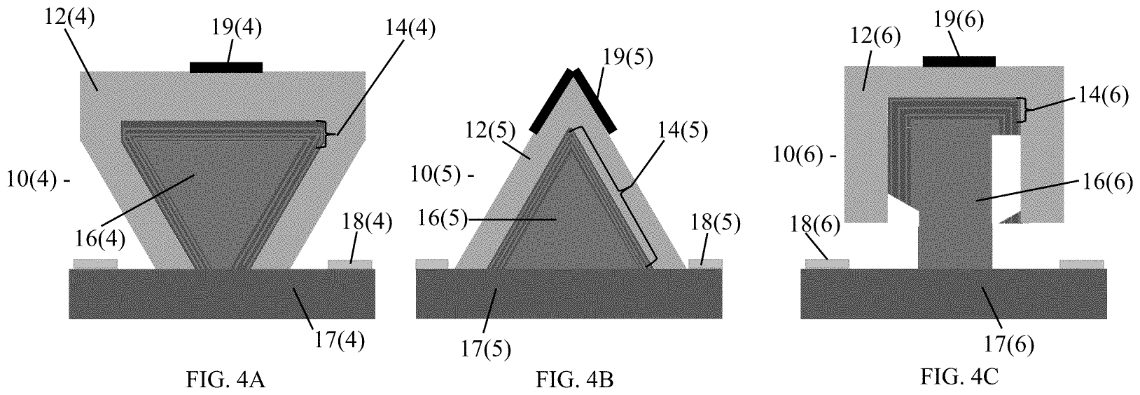

Referring to FIGS. 3A and 4A, a cross-sectional view of an example of an LED 10(4) with an engineered volume in another inverted pyramid shape for higher operating efficiencies that minimize or eliminate efficiency droop is illustrated. The LED 10(4) comprises the p-type layer 12(4), on the MQW region 14(4) which is on the n-type layer 16(4), which is on a bottom layer or substrate 17(4) coupled to a cathode contact 18(4) and an anode contact 19(4) coupled to the p-type layer 12(4), although the LED could have other types of layers and/or other elements in other configurations. Based on the set doping concentrations in the p-type layer 12(4) and the n-type layer 16(4), the LED 10(4) is configured in this example to have an inverted pyramid design to equalize or better balance the number of free holes in the volume of the p-type layer 12(4) to a number of free electrons in volume of the n-type layer 16(4), in the case of a higher acceptor ionization energy. Accordingly, in this example the p-type layer 12(4) is wrapped around the n-type layer 16(4) and a calculated total volume of the p-type layer 12(4) is closer, but still larger relative to another calculated total volume of the n-type layer 16(4) based on the identified concentration of charges to produce a more equal free carrier distribution, leading to less efficiency droop as illustrated in FIG. 5. By way of example, the LED 10(4) can be formed using similar exemplary techniques to those described above for LED 10(2), although other approaches may be used.

Referring to FIGS. 3B and 4B, a cross-sectional view of an example of an LED 10(5) with an engineered volume in another pyramid shape for higher operating efficiencies that minimize or eliminate efficiency droop is illustrated. The LED 10(5) comprises the p-type layer 12(5), on the MQW region 14(5) which is on the n-type layer 16(5), which is on a bottom layer or substrate 17(5) coupled to a cathode contact 18(5) and an anode contact 19(5) coupled to the p-type layer 12(5), although the LED could have other types of layers and/or other elements in other configurations. Again in this example, there can exist an opposite situation from that shown in FIGS. 3A and 4A, where in this example in FIGS. 3B and 4B the donor atoms again have a higher ionization energy than the acceptor atoms. To address the higher donor atom ionization energy, a pyramidal shape can be formed, in which a volume of the p-type layer 12(5) volume is calculated to be smaller relative to the n-type layer 16(5) so that there is again calculated equal distribution of charge carriers, e.g. electrons and holes, within a set percentage, such as 50% by way of example eliminating or leading to less efficiency droop as illustrated in FIG. 5. By way of example, the LED 10(5) can be formed using similar exemplary techniques to those described above for LED 10(2), although other approaches may be used.

Referring to FIGS. 3C and 4C, a cross-sectional view of an example of an LED 10(6) with an engineered volume in a T-shape for higher operating efficiencies that minimize or eliminate efficiency droop is illustrated. The LED 10(6) comprises the p-type layer 12(6), on the MQW region 14(6) which is on the n-type layer 16(6), which is on a bottom layer or substrate 17(6) coupled to a cathode contact 18(6) and an anode contact 19(6) coupled to the p-type layer 12(6), although the LED could have other types of layers and/or other elements in other configurations. Again in this example, there can exist a similar situation to that shown in FIGS. 1B and 3A, where the acceptor atoms again have a higher ionization energy than the donor atoms. To address the higher acceptor atom ionization energy, a volume of the p-type layer 12(6) volume is calculated to be larger relative to the n-type layer 16(6) so that there is again calculated equal distribution of charge carriers, e.g. electrons and holes, within a set percentage, such as 50% by way of example eliminating or leading to less efficiency droop as illustrated in FIG. 5. By way of example, the LED 10(6) can be formed using similar exemplary techniques to those described above for LED 10(2), although other approaches may be used.

Accordingly, as illustrated and described by way of the examples herein, this technology provides a number of advantages including providing methods for engineering volumes in LEDs for higher operating efficiencies that minimize or eliminate efficiency droop and devices thereof. With examples of this technology, an effective volume of doped layers of an LED are engineered or otherwise formed based on calculations so that electron concentration better matches hole concentration. For example, a more electron rich layer with a smaller volume balances a wider poor hole concentration layer with a larger volume. Better matching between electrons and holes with these engineered volumes leads to a reduction in the efficiency droop and promotes other advantages, such as enhanced light extraction efficiency by way of example

Having thus described the basic concept of the invention, it will be rather apparent to those skilled in the art that the foregoing detailed disclosure is intended to be presented by way of example only, and is not limiting. Various alterations, improvements, and modifications will occur and are intended to those skilled in the art, though not expressly stated herein. These alterations, improvements, and modifications are intended to be suggested hereby, and are within the spirit and scope of the invention. Additionally, the recited order of processing elements or sequences, or the use of numbers, letters, or other designations therefore, is not intended to limit the claimed processes to any order except as may be specified in the claims. Accordingly, the invention is limited only by the following claims and equivalents thereto.

What is claimed is:

1. A method for engineering at least one volume in a light emitting diode (LED) for higher operating efficiency, the method comprising:
forming a first semiconductor region of a light emitting diode doped with a first dopant concentration; and
forming a second semiconductor region of the light emitting diode doped with a second dopant concentration coupled to the first semiconductor region;
wherein the forming the first semiconductor region or the forming the second semiconductor region further comprises forming a volume of the first semiconductor region or another volume of the second semiconductor region based on a calculation so that an electron concentration in the first semiconductor region or the second semiconductor region substantially matches within a first set percentage a hole concentration in the other one of the first semiconductor region or the second semiconductor region.

2. The method as set forth in claim 1 further comprising:
forming at least one intermediate region between the first semiconductor region and the second semiconductor region;
wherein the first semiconductor region comprises one of a p-type or an n-type layer, the second semiconductor region comprises the other one of the p-type or the n-type layer, and the intermediate region comprises a multiple quantum wells region.

3. The method of claim 2, wherein the volume of the n-type layer is reduced with respect to the volume of the p-type layer for greater charge equivalency to the number of free holes in the p-type layer.

4. The method of claim 2, wherein the volume of the p-type layer is reduced with respect to the volume of the n-type layer for greater charge equivalency to the number of free electrons in the n-type layer.

5. The method of claim 2, wherein the volume of the n-type layer is increased with respect to the volume of the p-type layer for greater charge equivalency to number of free holes in the p-type layer.

6. The method of claim 2, wherein the volume of the p-type layer is increased with respect to the volume of the n-type layer for greater charge equivalency to the number of free electrons in the n-type layer.

7. The method of claim 1, wherein the volume of the first semiconductor region or the volume of the second semiconductor region are formed without any adjustments to the first dopant concentration or the second dopant concentration.

8. A light emitting diode (LED) system with an engineered volume for higher operating efficiency comprising:
a first semiconductor region of a light emitting diode doped with a first dopant concentration; and
a second semiconductor region of the light emitting diode doped with a second dopant concentration coupled to the first semiconductor region;
wherein a volume of the first semiconductor region or another volume of the second semiconductor region is based on a calculation so that an electron concentration in the first semiconductor region or the second semiconductor region substantially matches within a first set percentage a hole concentration in the other one of the first semiconductor region or the second semiconductor region.

9. The system as set forth in claim 8 further comprising:
at least one intermediate region between the first semiconductor region and the second semiconductor region;
wherein the first semiconductor region comprises one of a p-type or an n-type layer, the second semiconductor region comprises the other one of the p-type or the n-type layer, and the intermediate region comprises a multiple quantum wells region.

10. The system of claim 9, wherein the volume of the n-type layer is reduced with respect to the volume of the p-type layer for greater charge equivalency to the number of free holes in the p-type layer.

11. The system of claim 9, wherein the volume of the p-type layer is reduced with respect to the volume of the n-type layer for greater charge equivalency to the number of free electrons in the n-type layer.

12. The system of claim 9, wherein the volume of the n-type layer is increased with respect to the volume of the p-type layer for greater charge equivalency to number of free holes in the p-type layer.

13. The system of claim 9, wherein the volume of the p-type layer is increased with respect to the volume of the n-type layer for greater charge equivalency to the number of free electrons in the n-type layer.

14. The system of claim 8, wherein the volume of the first semiconductor region or the volume of the second semiconductor region are formed without any adjustments to the first dopant concentration or the second dopant concentration.
